(19) United States
(12) Patent Application Publication
(10) Pub. No.: US 2025/0194127 A1
(43) Pub. Date: Jun. 12, 2025

(54) HIGH-TEMPERATURE IMPLANT FOR GATE-ALL-AROUND DEVICES

(71) Applicant: Applied Materials, Inc., Santa Clara, CA (US)

(72) Inventors: Yan ZHANG, Westford, MA (US); Taegon KIM, Seoul (KR); Johannes M. VAN MEER, Middleton, MA (US); Naushad K. VARIAM, Marblehead, MA (US)

(73) Assignee: Applied Materials, Inc., Santa Clara, CA (US)

(21) Appl. No.: 18/534,071

(22) Filed: Dec. 8, 2023

(51) Int. Cl. H01L 29/66; H01L 21/223; H01L 21/3115; H01L 29/06; H01L 29/08; H01L 29/423; H01L 29/775

(52) U.S. Cl. CPC H10D 30/014; H01L 21/2236; H01L 21/31155; H10D 30/43; H10D 30/6735; H10D 62/121; H10D 62/151; H10D 64/018

(57) ABSTRACT

Approaches herein provide devices and methods with threshold voltage tunning for gate-all-around (GAA) based pFET or nFET devices. One method may include forming a GAA stack including a plurality of alternating first layers and second layers, wherein the GAA stack is positioned atop a bottom dielectric isolation (BDI) layer, and forming a source/drain (S/D) cavity by etching the plurality of alternating first layers and second layers. The method may further include forming an inner spacer in the S/D cavity, adjacent the plurality of alternating first layers and second layers, and performing an implant by directing ions to the GAA stack, through the S/D cavity, wherein the implant is performed at a temperature greater than 500° Celsius. The method may further include forming a S/D material in the S/D cavity following the implant.

### FIELD OF THE DISCLOSURE

The present embodiments relate to semiconductor device patterning, and more particularly, to devices and methods with improved threshold voltage tunning for gate-all-around (GAA) based MOSFET devices.

### BACKGROUND OF THE DISCLOSURE

As integrated circuit (IC) technologies progress towards smaller technology nodes, multigate devices have been used to improve gate control by increasing gate-channel coupling, reducing off-state current, and reducing short-channel effects. A multigate device generally refers to a device having a gate structure, or portion thereof, disposed over more than one side of a channel region. Fin-like field effect transistors (FinFETs) and gate-all-around (GAA) transistors, both also referred to as non-planar transistors, are examples of multigate devices that provide high performance and low leakage applications. The channel region of GAA transistors may be formed from nanowires, nanosheets (NS), or other nanostructures.

Tuning threshold voltage of GAA-type devices is quite challenging. The limited spacing between nanosheets leaves not enough room for work function metal deposition which is a traditional method for Vt tunning. Volume-less ALD dipole engineering provide a solution for n-type of nanosheet devices yet causes mobility degradation for p-type Nanosheet devices. Another conventional way for Vt tunning is channel doping. For nanosheet devices, vertical implant after dummy SiGe removal to dope the stacked channels causes high risk of damage on nanosheet channels and interfaces. Dopant uniformity is also hard to achieve.

Accordingly, improved approaches are needed for forming GAA FET devices.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method may include forming a GAA stack including a plurality of alternating first layers and second layers, wherein the GAA stack is positioned atop a bottom dielectric isolation (BDI) layer, and forming a source/drain (S/D) cavity by etching the plurality of alternating first layers and second layers. The method may further include forming an inner spacer in the S/D cavity, adjacent the plurality of alternating first layers and second layers, and performing an implant by directing ions to the GAA stack, through the S/D cavity, wherein the implant is performed at a temperature greater than 500° Celsius. The method may further include forming a S/D material in the S/D cavity following the implant.

In another aspect, a method for forming a gate-all-around (GAA) device may include forming a nanowire stack, the nanowire stack including a plurality of alternating first layers and second layers, and an outer gate spacer adjacent the plurality of alternating first layers and second layers, wherein the nanowire stack is positioned atop a bottom dielectric isolation (BDI) layer. The method may further include forming a source/drain (S/D) cavity by etching the plurality of alternating first layers and second layers, and by etching the outer gate spacer, forming an inner spacer in the S/D cavity, adjacent the plurality of alternating first layers and second layers, and performing an implant by directing ions to the inner spacer, through the S/D cavity, wherein the implant is performed at a temperature greater than 500° Celsius. The method may further include forming a S/D material in the S/D cavity following the implant.

In yet another aspect, a system may include one or more process chambers operable to: form a gate-all-around (GAA) stack including a plurality of alternating first layers and second layers, wherein the GAA stack is positioned atop a bottom dielectric isolation (BDI) layer, form a source/drain (S/D) cavity by etching the plurality of alternating first layers and second layers form an inner spacer in the S/D cavity, adjacent the plurality of alternating first layers and second layers, form a source/drain (S/D) cavity by etching the plurality of alternating first layers and second layers, and form an inner spacer in the S/D cavity, adjacent the plurality of alternating first layers and second layers. The system may further include an ion processing tool within the one or more chambers, wherein the ion processing tool is operable to perform an implant by directing ions to the GAA stack, through the S/D cavity, wherein the implant is performed at a temperature greater than 500° Celsius, and wherein a S/D material is formed in the S/D cavity following the implant.

### BRIEF DESCRIPTION OF THE DRAWINGS

The accompanying drawings illustrate exemplary approaches of the disclosure, including the practical application of the principles thereof, as follows:

FIG. 1 illustrates a perspective view of an exemplary ion treatment to a GAA-type device following channel and inner spacer formation, according to embodiments of the present disclosure;

FIG. 2 illustrates a perspective view of the GAA-type device following formation of a S/D material, according to embodiments of the present disclosure;

FIG. 3 illustrates a perspective view of an exemplary ion treatment to a GAA-type device following channel and inner spacer formation, according to embodiments of the present disclosure;

FIG. 4 illustrates a side view of a CFET during an implant process, according to embodiments of the present disclosure; and

FIG. 5 illustrates a perspective view of an exemplary plasma doping system, according to embodiments of the present disclosure.

FIG. 6 illustrates a perspective view of an example processing system, according to embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods, systems, and devices in accordance with the present disclosure will now be described more fully hereinafter with reference to the accompanying drawings, where various embodiments are shown. The methods, systems, and devices may be embodied in many different forms and are not to be construed as being limited to the embodiments set forth herein. Instead, these embodiments are provided so the disclosure will be thorough and complete, and will fully convey the scope of the methods to those skilled in the art.

Current art solutions for threshold voltage (Vt) tuning in GAA devices include gate module-like dipole engineering, new work function (WF) metal materials, and gas doping. However, these solutions have high costs and/or are not proven as effective. Another current art solution is a channel ion implant. However, this solution has a high chance of damaging channel/interfaces. To address these deficiencies, the solutions of the present disclosure provide a high-temperature S/D channel dopant to a nanosheet structure of a GAA device for improved Vt tuning, which reduces the risk of damage on the channel/interfaces, and reduces process costs. In some embodiments, solutions herein include a high-temperature ion implant or plasma doping process to dope sidewalls of the nanosheet structure, followed by a subsequent thermal process (e.g., bake or anneal) to drive the dopants into the channel(s). Thereafter, the risk of damage on the channels and interfaces is low.

In some embodiments, knobs like ion implant twist and tilt, as well as ion implant energy, dose can be used to improve conformity of cavity sidewall doping and thus channel doping uniformity without high-risk damage on nanosheet structures and interfaces. The threshold voltage of the complex GAA structures can be increased or decreased using the appropriate ion species type to the desired value with selected dose. Advantageously, the solutions of the present disclosure overcome the limited spaces between stacked nanosheets for Vt tuning without excessive damage to channels/interfaces.

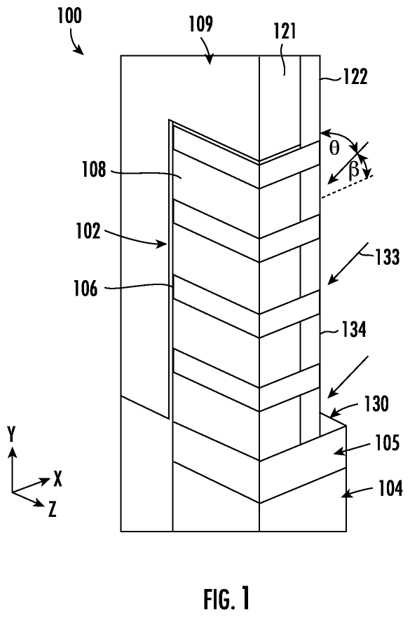

With reference to FIG. 1, an approach for forming a semiconductor device (hereinafter “device”) 100 according to one or more embodiments will be described. The device 100 may be a GAA device structure, a vertical GAA device structure, a horizontal GAA device structure, or a fin-like field effect transistor (FinFET) device structure. In some embodiments, the device 100 may be a stacked nanosheet complementary field effect transistor (CFET) device having a GAA structure. As shown, the device 100 may include a GAA stack 102 (sometimes referred to herein as a nanosheet stack) including a plurality of alternating first layers 106 and second layers 108 formed over a bottom dielectric isolation (BDI) layer 105 and a substrate base 104.

The term ‘nanosheet,’ as used herein, refers to a sheet or a layer having nanoscale dimensions. Further, the term ‘nanosheet’ is meant to encompass other nanoscale structures such as nanowires. For instance, ‘nanosheet’ can refer to a nanowire with a larger width, and/or ‘nanowire’ can refer to a nanosheet with a smaller width, and vice versa.

In various embodiments, the plurality of alternating first layers 106 and second layers 108 may include between two (2) and ten (10) first layers 106 and between two (2) and ten (10) second layers 108. A composition of the first layers 106 may be different than a composition of the second layers 108 to achieve etching selectivity and/or different oxidation rates during subsequent processing, for example. In some embodiments, the plurality of alternating first layers 106 and second layers 108 may include different materials, different constituent atomic percentages, different constituent weight percentages, and/or other different characteristics to achieve desired etching selectivity.

In the present embodiment, the first layers 106 may include silicon (Si) and the second layers 108 may include silicon germanium (SiGe), which has a different etch selectivity than silicon. Although non-limiting, a thickness of each first layer 106 may be about 1 nm to about 10 nm, a thickness of each second layer 108 may be about 1 nm to about 10 nm, and the two thicknesses can be the same or different. Although non-limiting, the plurality of alternating first layers 106 and second layers 108 may be epitaxially grown in the depicted interleaving and alternating configuration, layer-by-layer, until a desired number of semiconductor layers is reached.

The nanosheet stack 102 may be processed (e.g., etched) to form a plurality of structures, or nanosheets, only one of which is shown, extending in a vertical direction from the substrate base 104. Each of the nanosheets may include a set of opposing sidewall surfaces. Adjacent nanosheets may be separated by a trench. The nanosheets may be patterned by any suitable method. For example, the nanosheets may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. Embodiments herein are not limited in this context.

The BDI layer 105 may include any suitable material known to the skilled artisan. In one or more embodiments, the BDI layer 105 includes one or more of silicon oxide (SiOₓ), silicon nitride (SiN), silicon carbide (SiC), or a high-k material. In some embodiments, the high-k material is selected from one or more of aluminum oxide (Al₂O₃), hafnium oxide (HfO₂), and the like. In one or more specific embodiments, the BDI layer 105 comprises silicon oxide. In some embodiments, the BDI layer 105 is deposited on the substrate base 104 using conventional chemical vapor deposition methods.

According to an exemplary embodiment, the substrate base 104 may be a bulk semiconductor substrate. As used herein, the term “bulk semiconductor substrate” refers to a substrate in which the entirety of the substrate is comprised of a semiconductor material. The bulk semiconductor substrate may comprise any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In some embodiments, the semiconductor material is silicon (Si). In one or more embodiments, the substrate base 104 may include a semiconductor material, e.g., silicon (Si), carbon (C), germanium (Ge), silicon germanium (SiGe), germanium tin (GeSn), other semiconductor materials, or any combination thereof. In one or more embodiments, the substrate base 104 may include one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In some embodiments, the semiconductor material may be a doped material, such as n-doped silicon (n-Si), or p-doped silicon (p-Si). In some embodiments, the substrate may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers. In one or more embodiments, the dopant is selected from one or more of boron (B), gallium (Ga), phosphorus (P), arsenic (As), other semiconductor dopants, or combinations thereof.

A dummy gate structure 109 may also be formed over the nanosheet stack 102, a portion of which is shown. The dummy gate structure 109 may be formed atop the BDI layer 105, and may include a sacrificial gate having a gate material layer 121. In some embodiments, the gate material layer 121 may be an amorphous silicon (a-Si) or a polysilicon.

As further shown, a plurality of outer gate spacers 122 may be formed over the device 100, along a sidewall of the dummy gate structure 109. The outer gate spacers 122 may then be partially removed (e.g., etched), as demonstrated, to expose a portion of the nanosheet stack 102, namely, the plurality of alternating first layers 106 and second layers 108. Partially removing the outer gate spacers 122 causes a source/drain (S/D) cavity 130 to be formed through the plurality of alternating first layers and second layers 106, 108. Although non-limiting, the outer gate spacers 122 may be formed of a dielectric material such as silicon nitride, silicon oxide, silicon carbo-nitride, silicon oxynitride, silicon oxy carbo-nitride, or the like, and may have a single-layer structure or a multi-layer structure including a plurality of dielectric layers.

After formation of the S/D cavity 130, a lateral selective dry etch may be performed to trim the second layers 108 slightly (e.g., a few nm) to form gaps between Si nanosheets. One or more low-k materials may then be used to fill these gaps and form an inner spacer 134. In various non-limiting embodiments, low-k materials may include a dielectric having a dielectric constant less than about 7, for example, less than about 5 or even less than about 2.5, such as carbon containing silicon materials such as silicon oxycarbides (SiOC) or silicon carbides, silicon nitrides (SiN) or carbon containing silicon nitride materials (SiCN), and/or boron nitride (BN), silicon boron nitride (SiBN), silicon boron carbide nitride (SiBCN), carbon doped silicon oxide, fluorine doped oxide, porous dielectric, or combinations thereof.

As further shown, one or more implant processes may then be performed whereby ions 133 are directed into the GAA stack 102, after formation of the S/D cavity 130 and inner spacer 134. In some embodiments, the ions 133 may include p-type or n-type species depending on whether the GAA stack 102 is an nGAA stack or a pGAA stack, for example. In one non-limiting embodiment, the ions 133 are boron ions, which are directed into the exposed surfaces of the GAA stack 102 and into the inner spacer 134 at a non-zero angle (θ) relative to a plane (y-z plane) defined by an exterior surface of the GAA stack 102 within the S/D cavity 130. In some embodiments, the implant is performed at a temperature no less than approximately 500 degrees Celsius using a Thermion implant tool to reduce damage on Si of the GAA stack 102. Furthermore, in some embodiments, the non-zero twist angle (θ) and a tilt angle (B) of the boron ions 133 can be adjusted to enable adequate doping and uniformity. As shown, the tilt angle (B) corresponds to an angle between the boron ions 133 and a perpendicular 137 extending from the plane (y-z plane) defined by the exterior surface of the GAA stack 102.

In one non-limiting embodiment, the boron ions 133 are delivered as beamline ions into the GAA stack 102 at an implant energy of approximately 8 keV 8e14, a tilt angle (β)=7°, a twist angle (θ)=10°, and using a Thermion tool at platen temperatures greater than 500° C. to reduce implant damage. It will be appreciated that any of the implant energy, the twist angle, the tilt angle, and the temperature may be optimized, as desired, to enable sufficient doping of the GAA stack 102 with good conformity. An optional thermal process (e.g., pre-bake or rapid thermal anneal (RTA)) may then be performed to drive the boron into the channel regions.

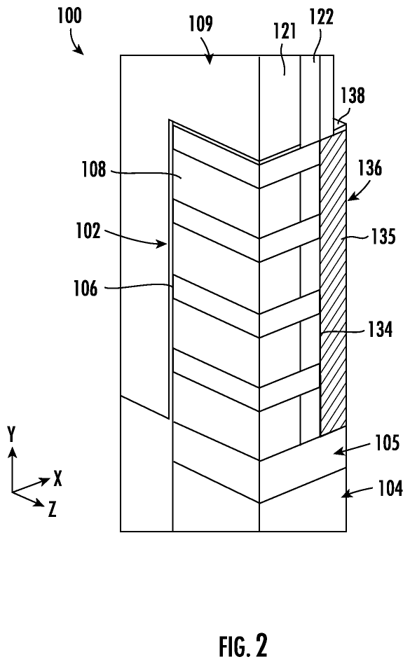

Next, as shown in FIG. 2, a S/D material 135 may then be epitaxially formed within the S/D cavities 130, to form a S/D 136. In some embodiments, an epitaxy process may use chemical vapor deposition (CVD) techniques (e.g., vapor phase epitaxy and/or Ultra-High Vacuum CVD), molecular beam epitaxy, other suitable epitaxial growth processes, or combinations thereof, to form the S/D 136. The epitaxy process can use gaseous and/or liquid precursors, which interact with the composition of the substrate base 104 and the first layers 106 of the GAA stack 102. As shown, the S/D 136 may be in direct contact with the first layers 106 and in direct contact with the inner spacers 134.

In some embodiments, the S/D 136 may be doped with p-type dopants. For p-type transistors, the S/D 136 may include silicon germanium or germanium, and can be doped with boron, other p-type dopant, or combinations thereof (for example, forming Si:Ge:B epitaxial source/drain features). Furthermore, the doping can be in-situ (i.e., doped during deposition by adding impurities to a source material of the epitaxy process) or ex-situ (e.g., doped by an ion implantation process subsequent to a deposition process). In some embodiments, a thermal process (e.g., pre-bake, RTA, and/or laser annealing) may be performed to activate dopants in the S/D 136. As shown, formation of the BDI layer 105 is performed before epi growth of the S/D 136, which may be done from front side or backside processes. In some embodiments, the boron ions 133 are directed to the GAA stack 102 before formation of the BDI layer 105. In other embodiments, the boron ions 133 are directed to the GAA stack 102 after formation of the BDI layer 105.

Although not shown, the device 100 may then be further processed using a RMG sequence whereby second layers 108 are removed from the GAA stack 102 using, for example, a wet etch process. In some embodiments, the etch process may be a lateral SiGe etch performed by a selective rapid plasma etch (SRP) device-optimized to remove the second layers 108. Various etching parameters can be tuned to achieve selective etching, such as etchant composition, etching temperature, etching solution concentration, etching time, etching pressure, source power, RF bias voltage, RF bias power, etchant flow rate, other suitable etching parameters, or combinations thereof. In some embodiments, the etch may be a selective isotropic dry etching process (e.g., a surface gas/radical reaction process) to the second layers 108. Furthermore, an etching temperature and/or an RF power may be tuned to selectively etch the second layers 108.

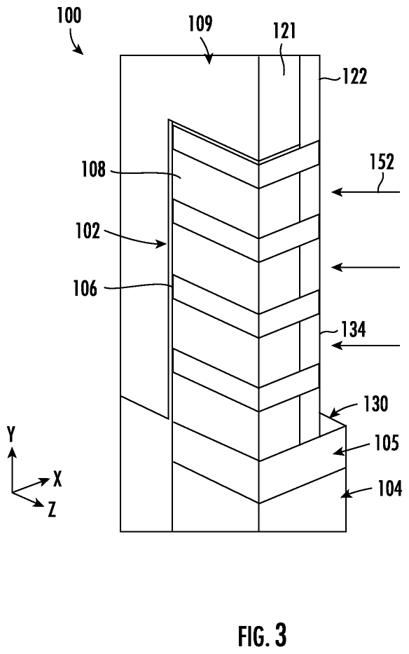

FIG. 3 demonstrates an alternative sidewall implant 152 approach, which may be performed to the inner spacer 134 and to the GAA stack 102 after the S/D cavity 130 and inner spacer 134 are formed. In this embodiment, the sidewall implant 152 is a plasma treatment, e.g., plasma doping (PLAD) or decoupled plasma treatment (DPX), which impacts the GAA stack 102, including the first and second layers 106, 108. This plasma doping is preferably done at high temperature (e.g., 500° C. or greater) to avoid any potential damage on Si along the sidewall. In various embodiments, the sidewall implant 152 may be delivered at a horizontal angle relative to the GAA stack 102, as shown, and/or vertically. In the example shown, the sidewall implant 152 may simultaneously impact the BDI layer 105, the substrate base 104, and the GAA stack 102, including the inner spacer 134 and the first layers 106. Although non-limiting, the sidewall implant 152 may be plasma treatment including boron, wherein the plasma dose may be constant or variable. In other embodiments, the plasma treatment may include an n-type species. As a result of the sidewall implant 152, uniformity is improved and damage is minimized on the GAA stack 102. In some embodiments, a low temp (e.g., approximately 500 C or lower) RTA may be performed after the sidewall implant 152 to drive the boron into the channel regions.

Following the sidewall implant 152, formation of the S/D 136 may be performed, as shown in FIG. 2 and described above. One or more thermal processes (e.g., pre-bake, RTA, and/or laser annealing) may also be performed to activate dopants in the S/D 136. In some embodiments, a contact etch stop 138 may be formed over the S/D material after the GAA stack 102 is annealed.

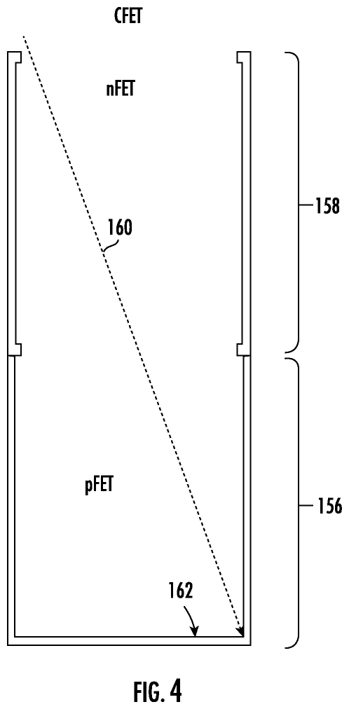

One beneficial application of the plasma treatment is demonstrated in FIG. 4, which shows a CFET S/D cavity including a pNS 156 beneath an nNS 158. More specifically, the lower nanosheets (not shown) in the stack will form a device of a first polarity, i.e., a PFET or an NFET, and the upper nanosheets (not shown) in the stack will form a device of a second/opposite polarity, i.e., an NFET if the lower device is a PFET, or vice versa. Gates of the CFET device are oriented orthogonal to the nanosheets. Due to this top-bottom arrangement, a large aspect ratio is present, for which conventional beam-line ion implant is not applicable due to shadowing effect. PLAD is the only option that could dope the sidewall of the S/D cavity of the CFET. In various embodiments, PLAD may dope N and/or P type dopants.

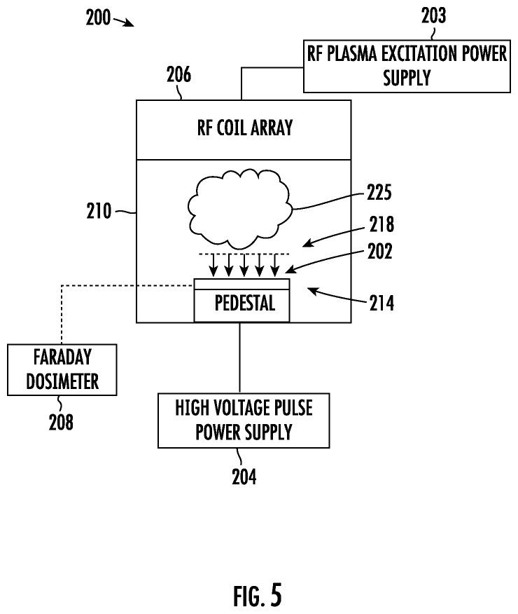

Referring to FIG. 5, an example system 200 (e.g., a PLAD system) operable to provide pulsed RF-excited continuous plasma doping to the device 100 of FIG. 3, will be described. As shown, the system 200 may include a plasma power supply 203, a voltage pulse power supply 204, an RF coil array 206, and a dosimeter 208. Within a plasma chamber 210 is a wafer/substrate 202, which may be the same or similar to the substrate base 104 described above. A platen/pedestal 214 may support the wafer 202, and a sheath 218 may be formed above the wafer 202. A temperature of the platen/pedestal 214 may be elevated (e.g., to 500° C. or greater) during plasma doping. The dosimeter 208 may be a Faraday dosimeter or other type of sensor that directly measures the dose of ions received by the wafer 202. Although non-limiting, the dosimeter can be located on the pedestal 214, proximate to the wafer 202.

During use, the plasma power supply 203 and the RF coil array 206 deliver radio frequency excitation to generate a plasma 225 when gaseous species are delivered into the plasma chamber 210. For example, the plasma power supply 203 may be an RF powered inductively coupled power source to generate inductively coupled plasma 225, as known in the art. Gaseous species may be delivered from one or more gas sources (not separately shown) to generate ions of any suitable species, such as boron.

The voltage pulse power supply 204 may generate a bias voltage between the wafer 202 and the plasma chamber 210. As such, when the voltage pulse power supply 204 generates a voltage between the plasma chamber 210 and the substrate 202, a similar, but slightly larger, voltage difference is generated between the plasma 225 and the substrate 202. In one non-limiting example, a 5000 (5 kV) voltage difference established between the plasma chamber 210 and the substrate 202 (or, equivalently, pedestal 214) may generate a voltage difference of approximately 5005 V to 5030 V between the plasma 225 and the substrate 202.

In some embodiments, the voltage pulse power supply 204 may generate a bias voltage as a pulsed voltage signal, wherein the pulsed voltage signal is applied in a repetitive and regular manner, to generate a pulse routine comprising a plurality of extraction voltage pulses. For example, a pulse routine may apply voltage pulses of 500 V magnitude, 1000 V magnitude, 2000 V magnitude, 5000 V magnitude, or 10,000 V magnitude in various non-limiting embodiments. The system 200 may further include a controller (not shown), to control the pulsing routine applied to the substrate 202, in order to provide the sidewall treatment 152.

According to various embodiments, the plasma 225 may be formed at least in part of ions that constitute an amorphizing species, wherein the amorphizing species may be any suitable ion capable of amorphizing an initially crystalline region of materials, such as the substrate 202. In various non-limiting embodiments, such suitable ions may include boron. When the plasma 225 is present in the plasma chamber 210, the controller may generate a signal for the voltage pulse power supply 204 to apply a pulse routine to the substrate 202, where the pulse routine constitutes a plurality of extraction voltage pulses. As such, when the extraction voltage pulses are applied between the substrate 202 and plasma 225, ions are extracted in pulsed form from the plasma 225, generating a plurality of ion pulses that are directed to the substrate 202.

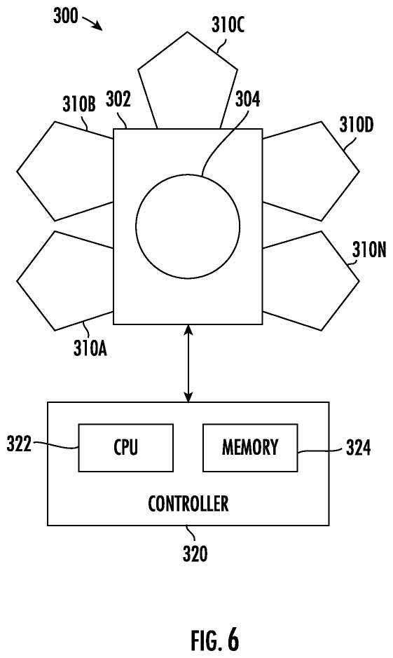

FIG. 6 shows a schematic of another example apparatus/system 300 according to embodiments of the disclosure. In some embodiments, the system 300 may be a cluster tool operable to perform processes necessary to form the device 100 described herein and shown in FIGS. 1-2. Although non-limiting, the system 300 may include at least one central transfer station/chamber 302 and one or more robots 304 within the transfer station/chamber 302, wherein the robot 304 is operable to move a robot blade and a wafer to and from each of a plurality of processing chambers 310A-310N connected with, or positioned adjacent to, the transfer station/chamber 302. In some embodiments, the processing chambers 310A-310N may support angled beamline ion implantation, material deposition, and material etching. The particular arrangement of process chambers and components can be varied depending on the cluster tool, and should not be taken as limiting the scope of the disclosure. In another example, one or more of the chambers may include multiple process regions within a same chamber, which permits a common supply of gases, common pressure control, and common process gas exhaust/pumping. Modular design of the system enables rapid conversion from one configuration to any other.

In some embodiments, processing chamber 310A may be a deposition chamber operable to deposit the GAA stack 102 as alternating first layers 106 and second layers 108. The first deposition chamber 310A may be further used to deposit the outer gate spacers 122 along the sidewall of each of the dummy gate structure 109, and to deposit the inner gate spacers 134 along the plurality of alternating first layers 106 and second layers 108 of the nanosheet stack 102. In some embodiment, processing chamber 310A may be further operable to form the gate dielectric 141 over the first layers 106, form the S/D 136 in the S/D cavity 130 following the implant, and to form the contact etch stop 136 over the S/D material after the GAA stack 102 is annealed. Although non-limiting, the deposition chamber may include one or more of an atomic layer deposition chamber, a plasma enhanced atomic layer deposition chamber, a chemical vapor deposition chamber, a plasma enhanced chemical vapor deposition chamber, or a physical deposition.

In some embodiments, processing chamber 310B may be an etch chamber operable to form the S/D cavities 130 through the plurality of alternating first layers and second layers 106, 108. The etch process may expose an upper surface of the BDI layer 105. Processing chamber 310B may be further operable to remove the second layers 108 from the GAA stack 102.

In some embodiments, processing chamber 310C may be operable to perform the implant process in which boron ions 133 are directed into the GAA stack 102 following formation of the S/D cavity 130. The boron ions 133 may be directed into the exposed surfaces of the first and second layers 106, 108 and into the inner spacer 134 at a non-zero angle θ (and optionally non-zero tilt angle β) relative to a plane defined by the exterior surface of the inner spacer 134. In some embodiments, the implant is performed at a temperature greater than approximately 500 degrees Celsius using a Thermion implant tool to reduce damage on Si of the GAA stack 102.

In some embodiments, processing chamber 310D may be operable to perform one or more thermal processes, such as the anneal to the GAA stack 102 following the boron implant and/or following formation of the S/D 136.

A system controller 320 is in communication with the robot 304, the transfer station/chamber 302, and the plurality of processing chambers 310A-310N. The system controller 320 can be any suitable component that can control the processing chambers 310A-310N and robot(s) 304, as well as the processes occurring within the process chambers 310A-310N. For example, the system controller 320 can be a computer including a central processing unit 322, memory 324, suitable circuits/logic/instructions, and storage.

Processes or instructions may generally be stored in the memory 324 of the system controller 320 as a software routine that, when executed by the processor 322, causes the processing chambers 310A-310N to perform processes of the present disclosure. The software routine may also be stored and/or executed by a second processor (not shown) that is remotely located from the hardware being controlled by the processor 322. Some or all of the method(s) of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor 322, transforms the general-purpose computer into a specific purpose computer (controller) that controls the chamber operation such that the processes are performed.

In various embodiments, design tools can be provided and configured to create the datasets used to pattern the semiconductor layers of the device, e.g., as described herein. For example, data sets can be created to generate photomasks used during lithography operations to pattern the layers for structures as described herein. Such design tools can include a collection of one or more modules and can also be comprised of hardware, software or a combination thereof. Thus, for example, a tool can be a collection of one or more software modules, hardware modules, software/hardware modules or any combination or permutation thereof. As another example, a tool can be a computing device or other appliance running software, or implemented in hardware.

For the sake of convenience and clarity, terms such as “top,” “bottom,” “upper,” “lower,” “vertical,” “horizontal,” “lateral,” and “longitudinal” will be used herein to describe the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporate the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, the present disclosure has been described herein in the context of a particular implementation in a particular environment for a particular purpose. Those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A method, comprising:
forming a gate-all-around (GAA) stack comprising a plurality of alternating first layers and second layers, wherein the GAA stack is positioned atop a bottom dielectric isolation (BDI) layer;
forming a source/drain (S/D) cavity by etching the plurality of alternating first layers and second layers;
forming an inner spacer in the S/D cavity, adjacent the plurality of alternating first layers and second layers;
performing an implant by directing ions to the GAA stack, through the S/D cavity, wherein the implant is performed at a temperature greater than 500° Celsius; and
forming a S/D material in the S/D cavity following the implant.

2. The method of claim 1, wherein the implant comprises n-type dopants or p-type dopants, and wherein the ions are directed into the inner spacer and into the first layers of the plurality of alternating first layers and second layers.

3. The method of claim 1, wherein the ions of the implant are directed as beamline ions into the GAA stack at a non-zero angle relative to a plane defined by a sidewall surface of the inner spacer.

4. The method of claim 1, wherein the implant comprises a plasma doping process.

5. The method of claim 1, wherein the ions are boron ions, and wherein the boron ions are directed to the GAA stack after formation of the BDI layer.

6. The method of claim 1, wherein the ions are boron ions, and wherein the boron ions are directed to the GAA stack before formation of the BDI layer.

7. The method of claim 1, wherein the BDI layer comprises one or more of silicon oxide, silicon nitride, silicon carbide, or a high-k material.

8. A method for forming a gate-all-around (GAA) device, comprising:
forming a nanowire stack atop a bottom dielectric isolation (BDI) layer, the nanowire stack comprising:
a plurality of alternating first layers and second layers; and
an outer gate spacer adjacent the plurality of alternating first layers and second layers;
forming a source/drain (S/D) cavity by etching the plurality of alternating first layers and second layers, and by etching an outer gate spacer located adjacent the nanowire stack;
forming an inner spacer in the S/D cavity, adjacent the plurality of alternating first layers and second layers;
performing an implant by directing ions to the inner spacer, through the S/D cavity, wherein the implant is performed at a temperature greater than 500° Celsius; and
forming a S/D material in the S/D cavity following the implant.

9. The method of claim 8, the implant comprises n-type dopants or p-type dopants, and wherein the ions are directed into the inner spacer and into the first layers of the plurality of alternating first layers and second layers.

10. The method of claim 8, wherein the ions are boron ions, and wherein the boron ions are directed as a beamline into the nanowire stack at a non-zero angle relative to a plane defined by a sidewall surface of the inner spacer.

11. The method of claim 8, wherein the implant comprises a plasma doping process.

12. The method of claim 8, wherein the ions are boron ions, and wherein the boron ions are directed to the nanowire stack after formation of the BDI layer.

13. The method of claim 8, wherein the ions are boron ions, and wherein the boron ions are directed to the nanowire stack before formation of the BDI layer.

14. The method of claim 8, wherein the S/D cavity is formed selective to a top surface of the BDI layer.

15. A system, comprising:
one or more process chambers operable to:
form a gate-all-around (GAA) stack comprising a plurality of alternating first layers and second layers, wherein the GAA stack is positioned atop a bottom dielectric isolation (BDI) layer;
form a source/drain (S/D) cavity by etching the plurality of alternating first layers and second layers; and
form an inner spacer in the S/D cavity, adjacent the plurality of alternating first layers and second layers; and
an ion processing tool within the one or more chambers, wherein the ion processing tool is operable to perform an implant by directing ions to the GAA stack, through the S/D cavity, wherein the implant is performed at a temperature greater than 500° Celsius, and wherein a S/D material is formed in the S/D cavity following the implant.

16. The system of claim 15, wherein the ion processing tool is operable to direct the ions into the inner spacer and into the first layers of the plurality of alternating first layers and second layers.

17. The system of claim 15, wherein the ion processing tool is beamline tool operable to direct the ions into the GAA stack at a non-zero angle relative to a plane defined by a sidewall surface of the inner spacer, and wherein the ions are boron ions.

18. The system of claim 15, wherein the ion processing tool is a plasma doping tool operable to perform a plasma doping process.

19. The system of claim 15, wherein the ion processing tool is operable to direct the ions to the GAA stack before or after formation of the BDI layer.

20. The system of claim 15, wherein the BDI layer comprises one or more of silicon oxide, silicon nitride, silicon carbide, or a high-k material.
